(19) United States
(12) Patent Application Publication
(10) Pub. No.: US 2026/0052950 A1
(43) Pub. Date: Feb. 19, 2026

(54) SEMICONDUCTOR ELEMENTS WITH HYBRID BONDING LAYERS

(71) Applicant: ADEIA SEMICONDUCTOR BONDING TECHNOLOGIES INC., San Jose, CA (US)

(72) Inventors: Rajesh Katkar, Milpitas, CA (US); Belgacem Haba, Saratoga, CA (US); Gaius Gillman Fountain, JR., Youngsville, NC (US); Cyprian Emeka Uzoh, San Jose, CA (US)

(21) Appl. No.: 18/806,545

(22) Filed: Aug. 15, 2024

(51) Int. Cl. H01L 23/00; H01L 21/56; H01L 21/683; H01L 25/065

(52) U.S. Cl. CPC H01L 24/80; H01L 21/568; H01L 21/6836; H01L 24/03; H01L 24/08; H01L 24/05; H01L 25/0657; H01L 2224/03462; H01L 2224/03616; H01L 2224/05647; H01L 2224/08145; H01L 2224/80895; H01L 2224/80896; H01L 2924/35

(57) ABSTRACT

A microelectronic interconnect structure having a pre-formed hybrid bonding layer is disclosed. The hybrid bonding layer is formed over a temporary carrier comprising a substantially flat upper surface. A routing structure comprising a device or metallization layers is then provided over the hybrid bonding layer. After the hybrid bonding layer coupled with the routing structure is properly reinforced, the temporary carrier is removed to reveal a bonding surface of the hybrid bonding layer. The interconnect structure can comprise an organic dielectric material interspersing the hybrid bonding layer and forming part of the routing structure, and as such exhibit bending flexibility.

### BACKGROUND

### Field

The field relates to hybrid bonding of semiconductor elements, and especially relates to forming a hybrid bonding layer having a hybrid bonding surface.

### Description of the Related Art

Hybrid bonding, as a low-temperature direct copper bonding technology, in particular, is being adopted for a broad range of high-performance semiconductor devices. Hybrid bonding can enable the continued growth of economically viable power-efficient computing, for example, utilizing chiplet-based heterogeneous integrated packaging technologies.

### BRIEF DESCRIPTION OF THE DRAWINGS

Specific implementations will now be described with reference to the following drawings, which are provided by way of example, and not limitation.

FIG. 1 is a schematic cross-sectional view of two semiconductor elements configured to be hybrid bonded together.

FIG. 2 is a schematic cross-sectional view of a bonded structure comprising the two semiconductor elements of FIG. 1.

FIG. 3 is a schematic cross-sectional view illustrating a carrier structure having a release layer and a dielectric layer formed on a temporary carrier.

FIG. 4A is a schematic cross-sectional view illustrating an example process stage for forming a patterned dielectric layer over the carrier structure of FIG. 3, for fabrication of an example microelectronic interconnect structure.

FIG. 4B is an alternative schematic cross-sectional view of FIG. 4A illustrating an example process stage for forming a layered dielectric material over the carrier structure of FIG. 3.

FIG. 5 is a schematic cross-sectional view illustrating an example process stage for filling cavities in the patterned dielectric layer shown in FIG. 4A with a conductive material to form contact pads thus forming a hybrid bonding layer, and an interface layer over the hybrid bonding layer.

FIG. 6 is a schematic cross-sectional view illustrating an example process stage for providing a routing structure over the hybrid bonding layer and the interface layer shown in FIG. 5.

FIG. 7A is a schematic cross-sectional view illustrating an example process stage for providing a support structure over the routing structure shown in FIG. 6. The support structure may represent an embodiment shown in subsequent figures.

FIG. 7B is a schematic cross-sectional view illustrating an example process stage for removing the carrier structure from the assembly shown in FIG. 7A, revealing a hybrid bonding surface.

FIG. 8 is a flowchart illustrating a fabrication method for forming a semiconductor interconnect structure, in accordance with some embodiments.

FIG. 9 is a schematic cross-sectional view illustrating an example process stage for forming an extra interface layer over the routing structure shown in FIG. 6.

FIG. 10 is a schematic cross-sectional view illustrating an example process stage for removing the carrier structure and for attaching another carrier to the interconnect structure shown in FIG. 9.

FIG. 11 is a schematic cross-sectional view illustrating the assembly of FIG. 10 in a flipped over position.

FIG. 12 is a schematic cross-sectional view illustrating an example process state for directly bonding the hybrid bonding layer of assembly of FIG. 11 to two semiconductor devices to form a bonded structure.

FIG. 13 is a schematic cross-sectional view illustrating an example process stage for providing a dielectric material to encapsulate the semiconductor devices of FIG. 12 in place and for removing the carrier.

FIG. 14 is a schematic cross-sectional view illustrating an example process stage for providing bumps to the bonded structure of FIG. 13 and preparing the bonded structure to bond to another substrate.

FIG. 15 is a flowchart illustrating a fabrication method for forming a bonded structure, in accordance with some embodiments.

FIG. 16 is a schematic cross-sectional view illustrating an example process stage for forming an extra interface layer over the routing structure shown in FIG. 6.

FIG. 17 is a schematic cross-sectional view of an example process stage for providing a substrate over the interconnect structure shown in FIG. 16.

FIG. 18 is schematic cross-sectional view of an example process stage for removing the carrier structure shown in FIG. 17 to form an interconnect structure.

FIG. 19 is schematic cross-sectional view of an example process stage for directly bonding the interconnect structure of FIG. 18 to two semiconductor devices to form a bonded structure.

FIG. 20 is a schematic cross-sectional view illustrating an example process stage for providing bumps to the bonded structure of FIG. 19 and configuring the bonded structure to bond to another substrate.

FIG. 21 is a flowchart illustrating a fabrication method for forming a bonded structure, in accordance with some embodiments.

FIG. 22 is a schematic cross-sectional view illustrating an example process stage for forming a patterned first dielectric layer on the carrier structure of FIG. 3, for fabrication of an example interconnect structure.

FIG. 23 is a schematic cross-sectional view illustrating an example process stage for overfilling trenches in the first dielectric layer shown in FIG. 22 with a dielectric material and forming a second dielectric layer over the first dielectric layer.

FIG. 24 is a schematic cross-sectional view illustrating an example process stage for patterning and etching cavities in the combined dielectric layers shown in FIG. 23.

FIG. 25 a schematic cross-sectional view illustrating an example process stage for filling the cavities shown in FIG. 24 to form a hybrid bonding layer, and forming an interface layer over the dielectric layers shown in FIG. 24.

FIG. 26 is a schematic cross-sectional view illustrating an example process stage for providing a routing structure over the hybrid bonding layer shown in FIG. 25, providing a support structure over the routing structure, and removing the carrier structure to reveal a hybrid bonding surface.

FIG. 27 is a schematic plan view illustrating a bonding surface of the hybrid bonding layer shown in FIG. 26.

FIG. 28 is a flowchart illustrating a fabrication method for forming an interconnect structure, in accordance with some embodiments.

### DETAILED DESCRIPTION

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

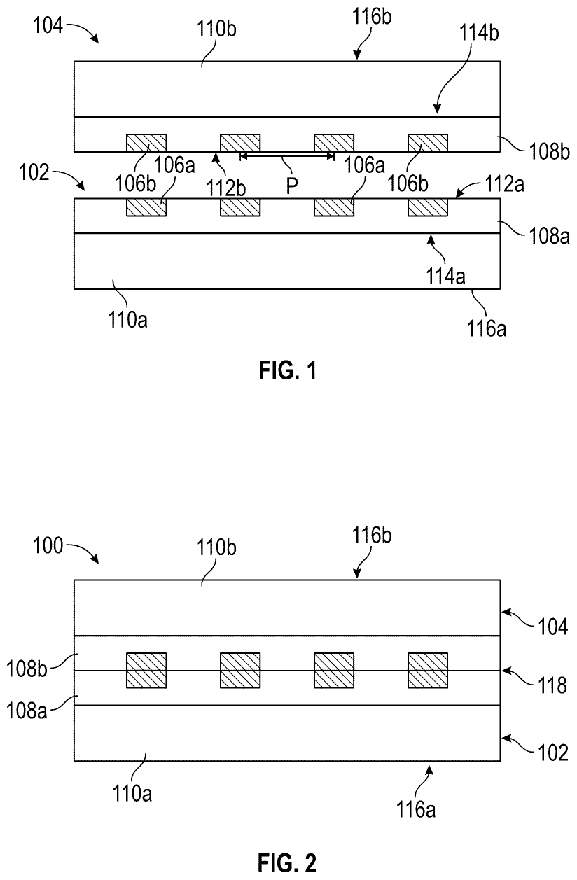

FIGS. 1 and 2 schematically illustrate cross-sectional side views of first and second elements 102, 104 prior to and after, respectively, a process for forming a directly bonded structure, and more particularly a hybrid bonded structure, according to some embodiments. In FIG. 2, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO3) or lithium niobate (LiNbO3), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å RMS. For example, the roughness of the bonding surfaces 112a and 112b can be in a range of about 0.1 Å RMS to 15 Å RMS, 0.5 Å RMS to 10 Å RMS, or 1 Å RMS to 5 Å RMS. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å RMS to 30 Å RMS, 3 Å RMS to 20 Å RMS, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials'melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1 prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

As explained above, to form the semiconductor elements 102, 104, substrates or device layers are provided, and, then the bonding layers 108a, 108b are formed over their respective substrates or device layers. Although FIG. 1 does not depict any routing or wiring layers on the semiconductor elements 102, 104, several dielectric and metallization layers (e.g., BEOL layers) may be present and the deposited bonding layers 108a, 108b can have topographic variations reflecting the routing layers underneath. Subsequently, the bonding surfaces 112a, 112b are planarized and prepared, e.g., by CMP, before the semiconductor elements 102, 104 are directly bonded to form the bonded structure 100. This means that the bonding layer (e.g., hybrid bonding layer) 108a or 108b is typically formed as the outermost layer of each of the semiconductors 102, 104. The use of CMP to planarize semiconductor elements is a complicated and costly process, as many different process parameters are considered when designing the CMP process that forms a desired conductive pad (e.g., contact pad) recess at the bonding surface. Some of such process and design parameters include, and not limited to, conductive pad sizes, conductive pad distribution, conductive pad shapes, conductive pad pitches, dielectric material, polishing pad hardness, speed of the polishing wheel/table, type of polishing slurry, permissible maximum pad recess, amount of conductive pad and dielectric material to be removed, permissible oxide rounding at the pad-dielectric interface, etc. The present application discloses a microelectronic structure or semiconductor element with a pre-formed bonding layer, e.g., having a bonding layer formed before device layers (e.g., semiconductor layers with active circuitry or devices) or interconnect layers (e.g., BEOL routing layers) are formed. Moreover, the processes disclosed herein can beneficially obviate the use of a CMP process, such that no CMP process is performed before direct bonding (or only a light CMP process is performed).

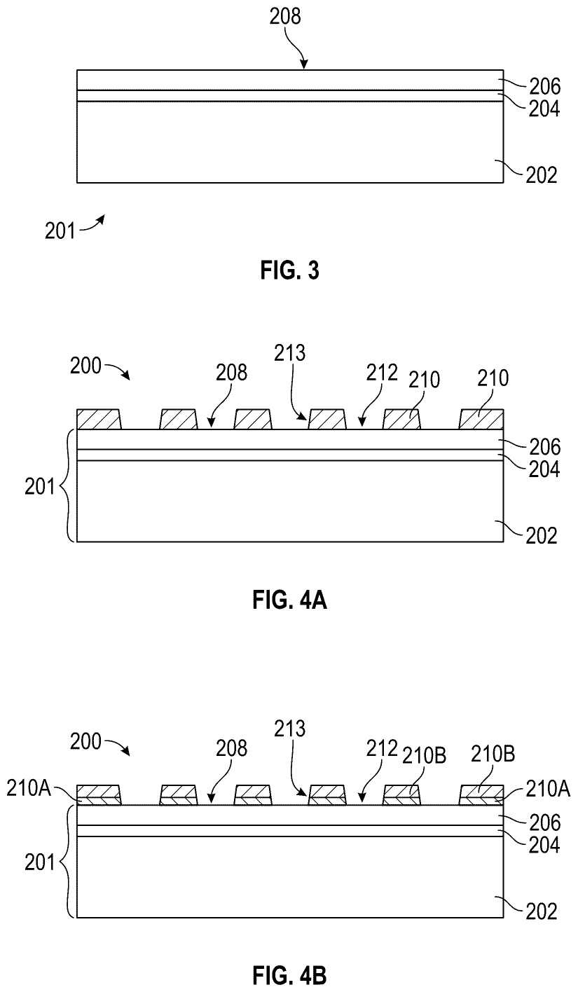

An example embodiment of a fabrication process for forming a microelectronic structure having a pre-formed hybrid bonding layer (e.g., bonding structure, direct bonding layer) with a bonding surface, is described herein with respect to the illustrated figures and charts. FIG. 3 shows a schematic cross-sectional view of a carrier structure 201 including a first temporary carrier 202 for forming a microelectronic structure thereon. The first temporary carrier 202 may comprise a ceramic or dielectric substrate (e.g., a glass substrate), a semiconductor substrate (e.g., a silicon substrate), or a wafer or panel of other suitable material that may possess desired mechanical properties, e.g., strength, rigidity and hardness to support the subsequent fabrication processes. As shown in FIG. 3, on top of the first temporary carrier 202 there can be provided additional temporary layers, e.g., a release layer 204 and a dielectric layer 206. The release layer 204 may have the advantage of releasing the carrier structure 201 from the microelectronic structure after the microelectronic structure is formed. The release layer 204 can comprise a thermal release layer (e.g., which can be heated to release), an optical release layer (e.g., a UV or IR release layer in which case exposure to UV or IR light causes release), or a chemical release layer (e.g., exposure to a chemical species can cause release). In some embodiments, the release layer 204 separated from the temporary carrier 202 may comprise a combination of the release layers described above formed by the thermal release method, optical release method and chemical release method. In some embodiments, the layer 204 can be an etch (or polish/grind) stop layer or a sacrificial layer and can comprise one or more organic or inorganic layers or a combination thereof. The dielectric layer 206 may comprise an inorganic non-conductive material, e.g., silicon nitride, silicon oxide, silicon oxynitride, silicon carbonitride, silicon oxycarbonitride, etc. In some embodiments, the dielectric layer 206 can also be an etch (or polish/grind) stop layer or a sacrificial layer. In some other embodiments, the dielectric layer 206 can comprise one or more organic or inorganic layers or a combination thereof. A flat or planarized upper surface 208 is formed, e.g., by CMP, on the top layer of the carrier structure 201, e.g., on the exposed top side of the dielectric layer 206 as shown in FIG. 3. Since the dielectric layer 206 (or another top layer of the carrier structure 201) comprises a material with uniform content and properties, substantially flat surface flatness of the upper surface 208 can be achieved by surface planarization, e.g., to within 1 nm RMS of surface roughness. Moreover, since the surface of the carrier structure 201 to be planarized to form the upper surface 208 is a homogenous surface comprising only one dielectric (and need not include contact pads or any underlying redistribution layers or wiring layers that may otherwise introduce topographic variations in the top surface of the carrier structure 201), the imperative to design a complicated CMP process to achieve the desired pad recess is eliminated. Instead, the CMP process may be designed only to yield a sufficiently planar surface for direct bonding without accounting for the effects of dishing on contact pads in the carrier structure 201.

In FIG. 4A, a dielectric bonding layer 210 is provided over the upper surface 208 of the carrier structure 201 to begin the formation of an interconnect structure 200, such as a microelectronic structure, a conductive pad, an interconnect via, a microelectronic element, a semiconductor element or a semiconductor device. The dielectric bonding layer 210 can be provided as a uniform layer (e.g., uniform thickness in various embodiments) over the upper surface 208. The dielectric bonding layer 210 may comprise an inorganic dielectric material, e.g., silicon oxide, silicon nitride, silicon oxynitride, silicon carbide, silicon oxycarbonitride, silicon carbonitride, diamond-like carbon, low K dielectric material, and high K dielectric material. Although, FIG. 4A depicts only one dielectric material to form the dielectric bonding layer 210, two or more layers of dielectric materials can also be deposited to form the dielectric bonding layer 210. For example, in FIG. 4B, a first thin layer is deposited to form a first dielectric bonding layer 210A (e.g., silicon oxynitride for less than 100 nm or less than 200 nm of thickness), followed by a comparatively thicker dielectric layer deposited to form second dielectric bonding layer 210B (e.g., silicon oxide between 100 nm and 2 μm of thickness). Subsequently, the dielectric bonding layer 210 is patterned and etched to form one or more trenches, vias or cavities 212 that penetrate through the dielectric bonding layer 210 and reach the upper surface 208. Five cavities 212 are shown in FIGS. 4A and 4B as an example. Although FIG. 4A or 4B depicts that bottom sides of all cavities 212 have the same widths, a cross-sectional area of each of the cavities 212 that is parallel to the upper surface 20, or a bottom surface of each of the cavities 212 can have any regular or irregular shape (for example, square, circular, oval, elliptical, rectangular, long traces, etc.). Although FIG. 4A or 4B depicts similar separation (or pitch) between adjacent cavities 212, any mixed separation, spacing or pitch between adjacent cavities 212 can be formed. The cavities 212 can be formed using conventional etching processes, such as isotropic etching processes, e.g., wet etching, and anisotropic etching processes, e.g., dry etching (e.g., plasma etching, reactive ion etching, etc.). The anisotropic etching processes, e.g., dry etching, generally create cavities with vertical sidewalls, while the isotropic etching processes, e.g., wet etching, create cavities with slanted or sloped sidewalls. In some embodiments, a wet etchant, such as buffered hydrofluoric acid (BHF), can be applied to etch silicon oxide. In some embodiments, dry etchants can be used, which may comprise hexafluoroethane (C₂F₆) plasma. Sidewalls 213 of the cavities 212 can be sloped or vertical in various embodiments. The slope of the side walls 213 may be controlled by wet etchant formulation. In the case of dry etch, the slope of the sidewall 213 of the cavity 212 can be controlled by the plasma etching parameters, substrate bias, chamber pressure, gas composition and flow rate. For each cavity 212, such sloped sidewalls typically result in a smaller cross-sectional area that is parallel to the upper surface 208 at a location close to the upper surface 208 than at a cross-sectional area away from the upper surface 208 and close to an upper surface of the dielectric bonding layer 210. For example, the wet etchant causes the sidewalls 213 to taper inwardly as the etch progresses from top to bottom as shown in FIG. 4A or 4B: for example, the cavity is wider at the upper surface of dielectric bonding layer 210 than at the upper surface 208. In some embodiments, the sidewalls 213 can be formed substantially vertical (e.g., the sidewalls 213 may form an approximately right angle with the upper surface 208), e.g., when the etching method is deep reactive-ion etching (DRIE). In this case, the cross-sectional area of the of the cavity 212 that is parallel to the upper surface 208 remains substantially unchanged from the upper surface of the dielectric bonding layer 210 through the dielectric bonding layer 210 to the upper surface 208.

In conventional hybrid bonding, in which a dielectric bonding material is deposited on other dielectric and/or metallization layers (e.g., BEOL layers) that are disposed over active layers (e.g., layers of an active semiconductor device), there can be certain thermal restrictions on depositing such bonding dielectric material. For example, certain semiconductor devices (e.g., DRAM memory chips) degrade if exposed to a temperature higher than 300° C. Since high quality dielectric materials may be deposited at a temperature higher than 300° C. or even 400° C., such high quality dielectric materials may not be suitable for bonding dielectric material for DRAM memory wafers or chips. As such, low quality dielectric materials (e.g., low temperature silicon oxide, tetraethoxysilane or TEOS, etc.) may be used for depositing bonding dielectric layers for DRAM memory wafers or chips. In the embodiments disclosed herein, the dielectric bonding layer 210 is deposited on the carrier structure 201, which is temporary in nature and comprises temporary substrates or removable/sacrificial layers. The thermal process restrictions for depositing dielectric bonding materials for certain semiconductor devices (e.g., low thermal budget restrictions) may not be restrictive in the embodiments disclosed herein. Hence the dielectric bonding layer 210 can be formed at optimal process conditions (e.g., high temperature deposition of silicon oxide) to achieve significantly better quality than the conventional dielectric bonding layers.

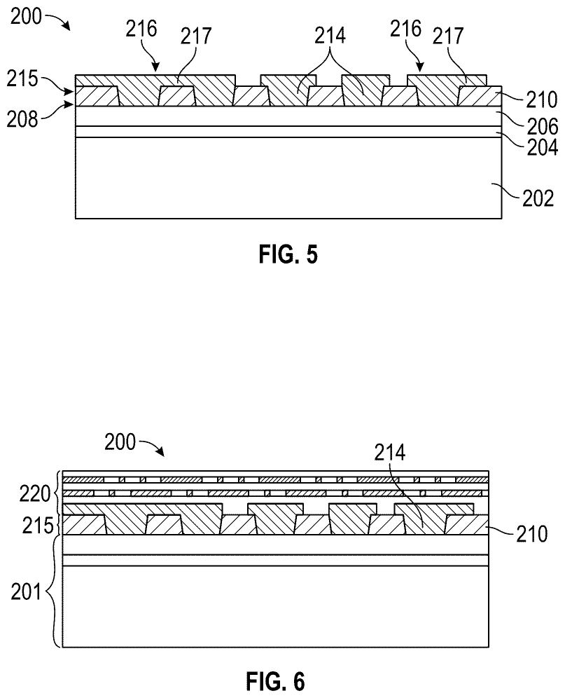

Referring to FIG. 5, the cavities 212 are over filled with a conductive material (e.g., by electroplating) comprising a conductive interface layer 216 disposed over and within cavities or trenches of the dielectric bonding layer 210. The conductive interface layer 216 can accordingly include one or more conductive contact features 214 (e.g., conductive features such as discrete pads formed in vias or cavities, contact traces disposed in trenches, etc.) configured to contact and bond to opposing conductive contact features. The conductive material can comprise a metal, such as copper, nickel, chromium, gold, indium, tin, platinum, silver, ruthenium, molybdenum, palladium, cobalt, zinc, tungsten, tantalum, titanium, aluminum, a metal silicide, and alloys thereof, or a non-metal conductive material, e.g., doped silicon. For example, copper can be electroplated into the cavities 212, and a polishing process, a selective metal etching process, or combination of both processes can remove the overburden of copper, followed by patterning of copper to produce the interface layer 216 (including the contact pads 214 and upper portions 217 of the interface layer 216 overlying dielectric bonding layer 210 (e.g., wiring layer, redistribution layer, etc.)) as shown in FIG. 5. In some embodiments, contact pads 214 can be dummy pads not connected to any other layer. In some other embodiments, the upper portions 217 of interface layer 216 may electrically short two (2) or more pads (with or without any active or dummy contact pads between the shorted pads). In some embodiments, a thin barrier layer (e.g., impurity doped titanium or doped tantalum, titanium nitride, tantalum nitride, etc.) and/or a seed layer (e.g., copper seed layer) is deposited in the cavities 212, prior to filling the cavities with the conductive material (e.g., copper). In some embodiments, the cavities 212 with a seed layer may be selectively filled by electroless plating methods. The unwanted portion of the coated metal may be removed by CMP method. In FIG. 5, the dielectric bonding layer 210 and the contact pads 214 of the interface layer 216 together form a hybrid bonding layer 215 (e.g., bonding structure, or part of an interconnect structure) of the interconnect structure 200, which will be further described subsequently. A lower surface of the hybrid bonding layer 215 (e.g., direct bonding layer), including the dielectric material 210 and the contact pads 214, are exposed at the upper surface 208. The upper portions 217 of the interface layer 216 may have gaps between adjacent traces, as shown in FIG. 5, within which dielectric material from routing structure 220 (FIG. 6) can be deposited. In some embodiments, conductive material is deposited in the cavities via a dual damascene process such that the contact pads 214 and the upper portions 217 of the interface layer 216 can be formed in one deposition and embedded in the dielectric bonding layer 210. In some embodiments, the interface layer 216 forms part of a back end of line (BEOL) structure.

In FIG. 6, a routing structure (e.g., supporting structure, additional wiring or routing layers, redistribution layers, etc.) 220 is provided over the interface layer 216. In some embodiments, the routing structure 220 may comprise multiple dielectric layers, e.g., routing layers including one or more dielectrics with embedded conductive vias and traces, device layers, or metallization layers, formed over the interface layer 216. In some embodiments, the routing structure 220 may include the upper portions 217 of the interface layer 216 and other layers provided thereover, as shown in FIG. 6. In some embodiments, one or more dielectric layers of the routing structure 220 can comprise organic materials (e.g., polyimide, PBO, polymer, etc.) and/or inorganic materials (e.g., silicon oxide, silicon nitride, etc.).

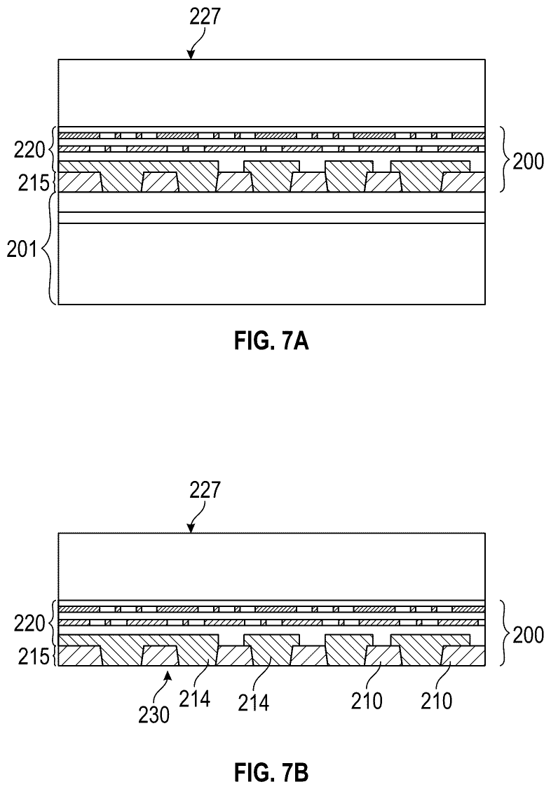

Referring to FIG. 7A, a support structure 227 is provided over (e.g., directly bonded to or adhered to) the routing structure 220 of the interconnect structure 200 shown in FIG. 6, forming a microelectronic assembly comprising the interconnect structure 200 coupled with the carrier structure 201 at the underside and the support structure 227 at upper side. The support structure 227 can structurally reinforce the interconnect structure 200, and take different forms or embodiments. Further, when the carrier structure 201 is released from the interconnect structure 200, a bonding surface is revealed. The support structure 227 can serve as a handle (e.g., handle wafer) to support the released interconnect structure 200 as the interconnect structure 200 is directly bonded to another surface or structure. Example embodiments of the support structure 227 coupled with the interconnect structure 200 will be shown and described below. In various embodiments, the support structure 227 can comprise a temporary carrier, similar to the carrier structure 201. In other embodiments, the support structure 227 can comprise an active or passive device, an encapsulated structure, organic printed circuit board (PCB, PC board) material, semiconductor material, a wafer or a panel, reconstituted dies/PCB, etc.

In FIG. 7B, the carrier structure 201 including the first temporary carrier 202 is removed so that a bonding surface 230, which is the lower surface of the hybrid bonding layer 215 attached to the upper surface 208 of the carrier structure 201, is released and exposed to atmosphere or the fabrication environment. The removing processes will be further described below with respect to FIG. 10.

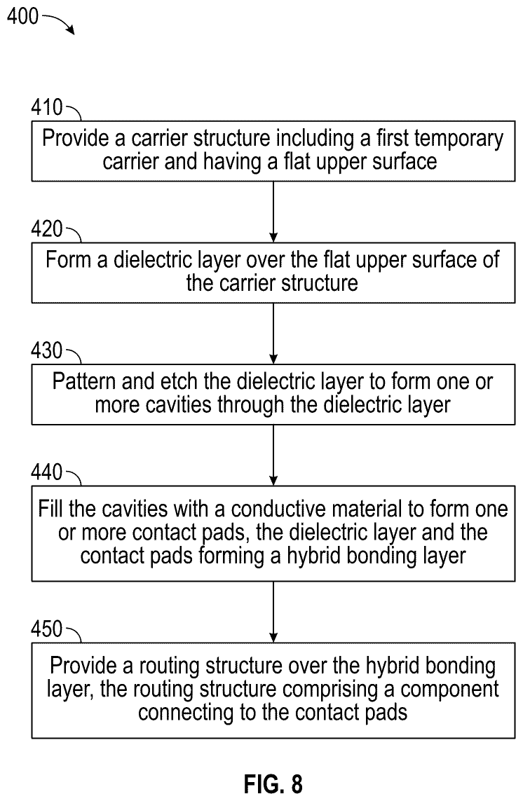

The fabrication method to fabricate the interconnect structure 200 described above with respect to FIGS. 1-6 are further illustrated as a process flowchart 400 shown in FIG. 8. According to flowchart 400, at block 410 a carrier structure is provided to have a substantially flat upper surface. The carrier structure comprises a first temporary carrier, and may further comprise one or more of a release layer, an etch stop layer, a sacrificial layer and a dielectric layer. In some embodiments, the dielectric layer can also act as an etch stop layer and/or a sacrificial layer. At block 420, a dielectric material layer is provided over the upper surface of the carrier structure. At block 430, the dielectric material layer is patterned and etched to form one or more cavities that go through the dielectric material layer to reach the upper surface. Sidewalls of the one or more cavities can be sloped inwardly so that a cross-sectional area of each cavity that is parallel to the upper surface of the carrier structure and located close to the upper surface is smaller than a cross-sectional area of the cavity away from the upper surface of the carrier structure and close to an upper surface of the dielectric material layer. In other embodiments, the sidewalls of one or more cavities can be substantially vertical so that a cross-sectional area of each cavity that is parallel to the upper surface of the carrier structure is substantially unchanged from the upper surface of the carrier structure through the dielectric material layer to the upper surface of the of the dielectric material layer. Subsequently at block 440, a conductive material to form one or more contact pads is deposited (e.g., electroplated) in one and more cavities and an interface layer over the dielectric material layer. The dielectric material layer and the contact pads together form a hybrid bonding layer. In some embodiments, the cavities and an additional routing or wiring layer can be formed in dual damascene process. At block 450, a routing structure is provided over the hybrid bonding layer. The routing structure may comprise a device or component that is connected to the contact pads of the hybrid bonding layer.

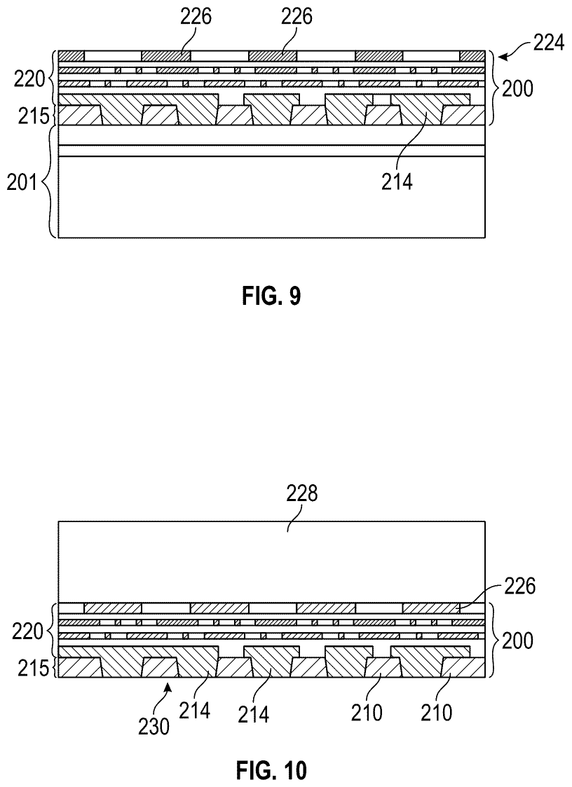

Referring now to FIGS. 9-14, example processes of forming an embodiment of the support structure 227 coupled with the interconnect structure 200 are illustrated. In FIG. 9, an extra interface layer 224 may be deposited over the routing structure 220 in a buildup process to sequentially build up the routing structure 220 over the bonding layer 215. The interface layer 224 may include conductive features (e.g., contact pads/terminals) 226 formed therein. The conductive features 226 can be larger in size than the contact pads 214 of the hybrid bonding layer 215 and can be spaced by a courser pitch than the contact pads 214, e.g., serving as fan-out contact pads/terminals. As such, the conductive features 226 can connect to another device or substrate, e.g., by hybrid bonding or solder bonding. In some embodiments, the separation (e.g., minimum pitch) between the adjacent contact pads 214 can be from 0.2 μm to 2 μm, from 0.5 μm to 5 μm or from 1 μm to 20 μm. The separation (or minimum pitch) between the adjacent conductive features 226 can be equal to or greater than separation between the contact pads 214. In some embodiments, the separation between the conductive features 226 can be 2 to 10 times or 10 to 50 times greater than the separation between the contact pads 214. In some embodiments, the minimum size (e.g., diameter or side width) of the contact pads 214 can be from 0.1 μm to 3 μm or from 1 μm to 10 μm. In some embodiments, the size of the conductive features 226 can be same or 2 to 10 times greater than the size of the contact pads 214. In some embodiments, the shape of the of the contact pads 214 and conductive features 226 viewed from top to bottom direction in FIG. 9, for example, can be same (e.g., circular, square, hexagonal, etc.). In some embodiments, the shape of the of the contact pads 214 and the conductive features 226 can be different (e.g., the contact pads 214 can be square or hexagonal in shape and the conductive features 226 can be circular in shape).

As shown in FIG. 9 and as used herein, the routing structure 220 may be expanded to include the interface layers 216, 224 below and above. At this stage of processing, the interconnect structure 200 comprises the hybrid bonding layer 215 coupled with the routing structure 220. Further, the interconnect structure 200 and the carrier structure 201 together form an assembly shown in FIG. 9.

In FIG. 10 a second temporary carrier 228 is provided over an upper surface of the routing structure 220 of the interconnect structure 200 of FIG. 9. The second temporary carrier 228 is an example embodiment of the support structure 227 shown in FIGS. 7A and 7B. As with respect to the first temporary carrier 202, the second temporary carrier 228 may comprise a ceramic or dielectric substrate (e.g., a glass substrate), a semiconductor substrate (e.g., a silicon substrate), or a wafer or panel of other suitable material that may possess desired mechanical properties, e.g., strength, rigidity and hardness to support the subsequent fabrications processes.

As shown in FIG. 10, the carrier structure 201 including the first temporary carrier 202 is removed so that a bonding surface 230, which is the lower surface of the hybrid bonding layer 215 formed over the upper surface 208 of the carrier structure 201, is released and exposed to atmosphere or the fabrication environment. The removing of the carrier structure 201 may comprise one or a combination of processes, including grinding/polishing, etching, releasing by UV light or heat, and polishing/grinding. For example, in the case that the carrier structure 201 comprises the release layer 204, the release layer 204 can be removed by the suitable releasing method, e.g., heating to release when the release layer 204 is a thermal release layer, exposure to UV or IR light when the release layer 204 is an optical release layer, or exposure to a chemical species or an etchant (e.g., wet etch process) to release when the release layer is a chemical release layer. In the case that the carrier structure 201 comprises the dielectric layer 206, after removing the outmost layer(s), e.g., the temporary carrier 202 and possibly the release layer 204, the dielectric layer 206 is removed by etching or polishing (e.g., when the dielectric layer 206 is an etch stop layer. In some embodiments, the first temporary carrier 202 of the carrier structure 201 can be removed by grinding and/or polishing, to expose the release layer 204 and/or the dielectric layer 206. Subsequently, the release layer 204 and/or the dielectric layer 206 can be removed by one or more of the processes as described above. As such, when the carrier structure 201 is removed, the flatness of the upper surface 208 of the carrier structure 201 is effectively transferred to the bonding surface 230 of the bonding layer 215. In some embodiments, removing the carrier structure 201 to expose the bonding surface 230, which is the lower surface of the hybrid bonding layer 215, preserves the flatness of the upper surface 208 of the hybrid bonding layer 215 especially for the dielectric portion of the hybrid bonding layer 215 (e.g., within 1 nm RMS surface roughness). The bonding surface 230 of the hybrid bonding layer 215 is now exposed and can be further prepared, if needed, to directly bond to another element. In some embodiment, cleaning and light CMP of the exposed bonding surface 230 of the hybrid bonding layer 215 may need to be performed.

In the illustrated embodiment, the carrier structure 201 is removed after the second temporary carrier 228 is provided. As such, the interconnect structure 200 can be continuously reinforced during the transition. In this way, when the carrier structure 201 is removed, the interconnect structure 200 is effectively transferred to and supported by the second temporary carrier 228 thus forming a new assembly for processing.

In accordance with the methods described herein, the hybrid bonding layer 215 is formed on top of a temporary carrier structure 201 before other interconnect layers or device layers are formed. Compared with conventional methods of forming a hybrid bonding layer, which typically happens after the device and interconnect layers are formed and utilizes substantial preparation of the bonding surface before hybrid bonding, the bonding layer 215 may be considered a pre-formed bonding layer. Preparing (e.g., by CMP) a conventional hybrid bonding surface, e.g., having contact pads embedded in a dielectric material, is complicated because of the different materials involved (e.g., bonding dielectric, copper pads, etc.). These different materials have different chemical and mechanical properties, such as hardness, which result in surface height differences and dishing, especially at the interface between the materials and at the oxide rounding, etc. As described above, the dielectric layer 206 (or another top layer of the carrier structure 201 if the dielectric layer does not exist) comprises a material with uniform content and properties, polishing the upper surface 208 of the top layer is comparatively straightforward and produces a high degree of smoothness and flatness. As such, the upper surface 208 of the carrier structure 201 can be made substantially flat, e.g., within 1 nm RMS surface roughness. The bonding surface 230 of the bonding layer 215, which is deposited and formed over the smooth and flat upper surface 208, can also be substantially flat as it mates with the upper surface 208 of the carrier structure 201.

Deposition processes used to deposit the dielectric bonding layer 210 and pads 214 can cause the dielectric bonding layer 210 and conductive pads 214 to conform to the flat upper surface 208 of the carrier structure 201. Accordingly, since the bonding layer 215 is deposited over the flat upper surface 208, the flatness of the upper surface 208 is transferred to the bonding surface 230. The bonding pads in such transferred bonding surface 230 may achieve no dishing and may effectively avoid using of complicated and expensive CMP processes on the hybrid bonding surface 230 altogether or significantly simplify the CMP process. In some embodiments the hybrid bonding surface 210 may be slightly polished at low pressure, for example, below 0.5 psi, to remove organic residue/debris from the temporary carrier to avoid contaminating the bonding surface 230.

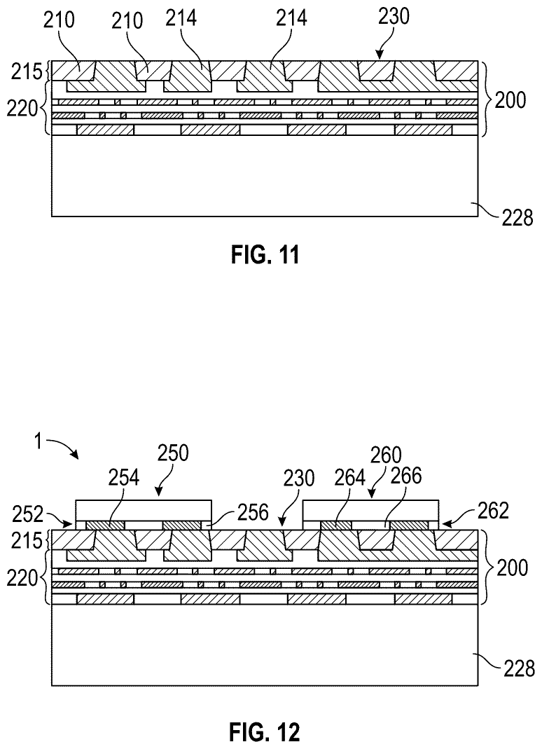

In FIG. 11, the assembly of the interconnect structure 200 coupled with the second temporary carrier 228 is turned upside down to allow the bonding surface 230 to face upward. After removing the carrier structure 201, the bonding surface 230 may undergo a preparation process for hybrid bonding depending on the processes of removing the carrier structure 201 as described above. In the illustrated embodiment, no CMP process is used on the hybrid bonding surface 230 of the bonding layer 215. In other embodiments, however, the preparation processes may include cleaning and a CMP step, e.g., a light CMP step to touch up the bonding surface 230, followed by plasma activation as explained herein. Accordingly, in various embodiments, no CMP is needed. As described above, the preparation processes for the bonding layer 230 may be substantially simpler than the preparation processes for conventionally formed interconnect structures having a hybrid bonding layer, because the bonding surface 230 is formed on a substantially flat upper surface 208 of the carrier structure 201. As such, there is no need to remove thick layers of 2 or more materials of varying shapes, sizes and hardnesses and to planarize a rough or bumpy surface.

As illustrated in FIG. 11, the sloped sidewall of the contact pad 214 extends from the bonding surface 230 of the hybrid bonding layer 215 outwardly from the bonding surface 230 and from a center line (not shown) of the contact pad 214. The contact pad 214 and surrounding structures is flipped over as compared with the contact pads 214 shown in FIG. 4A. The contact pad 214 shown in FIG. 11 as bounded by the left and right sloped lines, an upper surface that is part of the bonding surface 230, and a lower surface that is between the bonding layer 215 and the routing structure 220, takes an approximately trapezoidal shape as viewed in a side cross section of a contact pad 214. Taking a 3D perspective view, the contact pad 214 may have a conical or pyramidal shape. This means that a cross-sectional area of the contact pad 214 that is parallel to the bonding surface 230 increases with a distance from the bonding surface 230 and in the direction away from the bonding surface 230. For example, a diameter or width of the lower surface of the contact pad 214 shown in FIG. 11 is longer than a diameter or width of the upper surface of the contact pad 214. In some embodiments the sidewalls of the contact pad 214 are substantially vertical, for example, when the method to form the cavity for the contact pad 214 is DRIE. In this case, the cross-sectional view of the contact pad 214 is substantially rectangular. As such, the upper surface and the lower surface of the contact pad 214 are substantially equal.

If the bonding surface 230 is lightly polished after removing the carrier structure 201, the upper surface of the contact pad 214 can be slightly dished from the bonding surface 230, but the amount of dishing may be less than the amount of dishing or recess found in a typical CMP process for hybrid bonding. In some embodiments, no CMP is performed after the release of the carrier structure 201. As such, the contact pad has no substantial dishing and the upper surface of the contact pad 214 is substantially flat.

Referring to FIG. 12, after the bonding surface 230 is prepared, the assembly of the interconnect structure 200 coupled with the second temporary carrier 228 is directly bonded to at least one device, for example, two semiconductor devices (e.g., microelectronic devices, semiconductor elements) 250, 260 shown in FIG. 12. As such a bonded structure 1 is formed comprising the interconnect structure 200 directly bonded (e.g., hybrid bonded) with the semiconductor devices 250, 260. The semiconductor device 250 comprises a hybrid bonding layer 252, that includes a dielectric material 256 and at least one conductive feature 254 at least partially embedded in the dielectric material 256 and exposed for bonding at the bond interface. Likewise, the semiconductor device 260 comprises a hybrid bonding layer 262, that includes a dielectric material 266 and at least one conductive feature 264 at least partially embedded in the dielectric material 266 and exposed for bonding at the bond interface. During the hybrid bonding process, the dielectric bonding layer 210 of the hybrid bonding layer 215 of the interconnect structure 200 is directly bonded to the dielectric material 256 of the hybrid bonding layer 252 of the semiconductor device 250 and to the dielectric material 266 of the hybrid bonding layer 262 of the semiconductor device 260 without an intervening adhesive. Likewise, the contact pads 214 of the hybrid bonding layer 215 is directly bonded to the conductive features 254 of the hybrid bonding layer 252 of the semiconductor device 250 and to the conductive features 264 of the hybrid bonding layer 262 of the semiconductor device 260 without an intervening adhesive. In some examples, one or both the semiconductor devices 250 and 260 can be stack of dies. In some examples, the semiconductor device 250 can be a processor die (e.g., CPU, GPU, NPU, TPU, etc.) and the semiconductor device 260 can be a memory die or a stack of memory dies (e.g., NAND, HBM, etc.). In some examples, the semiconductor device 250 and/or 260 can be an electronic integrated circuit (EIC) and in some other examples, interconnect structure 200 can be a photonic integrated circuit (PIC).

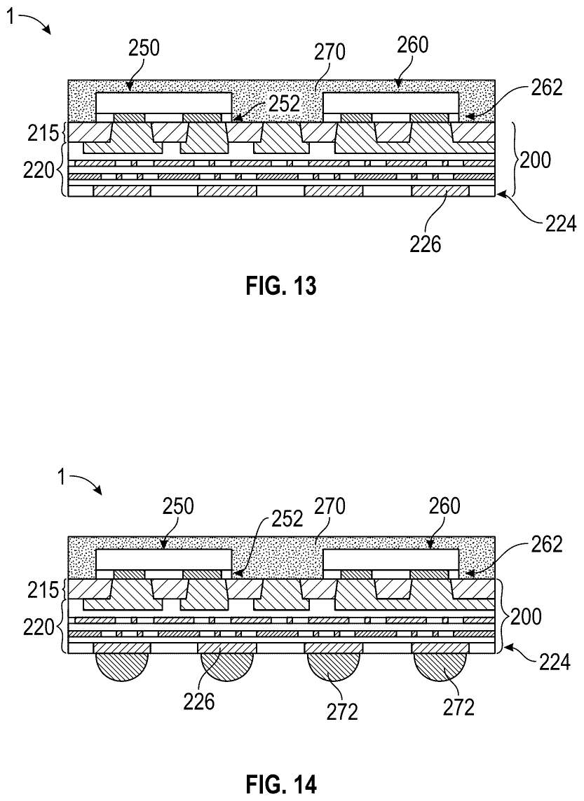

As shown in FIG. 13, an encapsulant (e.g., a dielectric material) 270 is deposited over the semiconductor devices 250, 260, embedding the semiconductor devices 250, 260 over the interconnect structure 200. The encapsulant 270 can comprise one or more inorganic dielectric layers (e.g., silicon oxide, silicon nitride, etc.), or one or more organic layers (e.g., molding compound, epoxy, resin, polymer, etc.). In this way, the bonded structure 1 is mechanically reinforced by the encapsulant 270. In some embodiments, the top surface of the encapsulant 270 can be polished or planarized. In some embodiments, the semiconductor devices 250 and 260 are known good dies (KGD) that are attached to the interconnect structure 200 and are encapsulated to effectively form a reconstituted wafer or panel of the semiconductor devices. The routing layers on the routing structure 220 may go beyond edges of the dies or the routing/wiring on known good dies, e.g., the semiconductor devices 250, 260. Subsequently, the second temporary carrier 228 is removed from the bonded structure 1, leaving the conductive features 226 of the interface layer 224 of the routing structure 220 exposed. In FIG. 14, solder bumps 272 are provided at the conductive features 226, so that the bonded structure 1 is prepared to be bonded to another substrate, e.g., PCB. In other embodiments, the interface layer 224 including the conductive features 226 can be prepared for hybrid bonding to another element, device, wafer or panel.

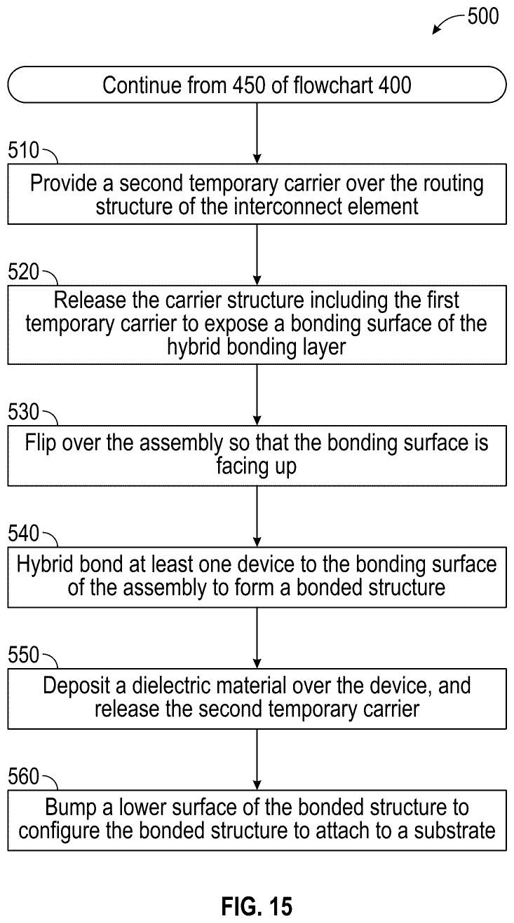

Referring now to FIG. 15, a fabrication process flowchart 500 is illustrated to produce the bonded structure 1 schematically shown in FIG. 14, starting from the assembly of the interconnect structure 200 coupled with the carrier structure 201 schematically shown in FIG. 6. According to flowchart 500, the process can be a continuation from the last stage of flowchart 400 shown in FIG. 8. At block 510, a second temporary carrier is provided over the routing structure of the interconnect structure. At block 520, the carrier structure including the first temporary carrier is removed to reveal the bonding surface of the hybrid bonding layer. The bonding surface may be prepared for hybrid bonding. At block 530, the assembly of the interconnect structure coupled to a second temporary carrier is flipped over so that the bonding surface faces up. Subsequently at block 540, the assembly is directly bonded to at least one semiconductor device to form a bonded structure. The dielectric material of the interconnect structure is directly bonded to a dielectric material of the semiconductor device, and the contact pad of the interconnect structure is directly bonded to a conductive feature of the semiconductor device. At block 550, a dielectric material is deposited over the semiconductor device and encapsulate the semiconductor device that is bonded with the interconnect structure. At block 560, a lower side of the interconnect structure is bumped, e.g., by solder balls, as such the bonded structure is configured to bond to another substrate, e.g., a PCB.

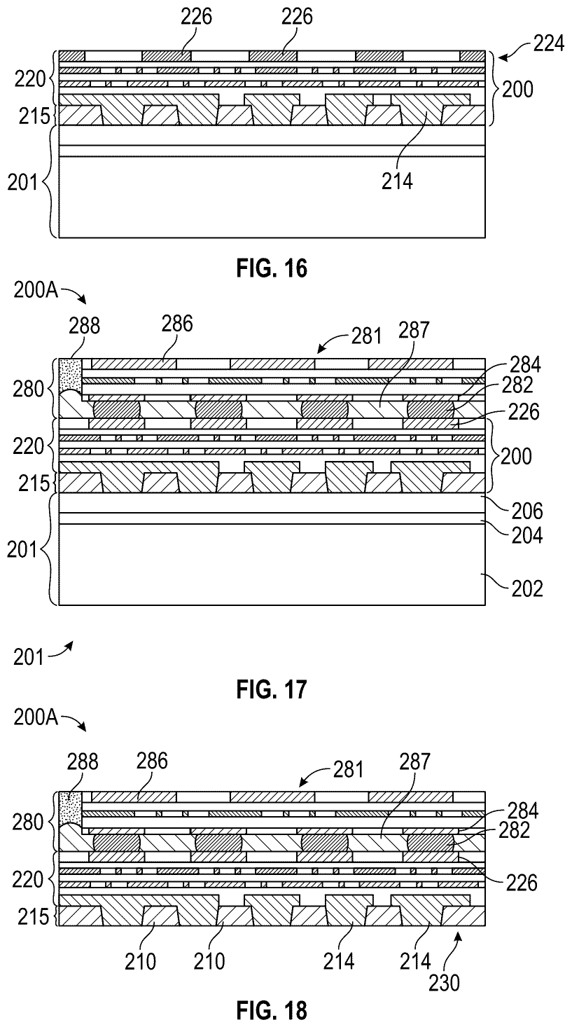

In addition to the embodiment of the interconnect structure 200 described above, other embodiments can be fabricated to have pre-formed bonding surfaces. FIGS. 16-20 show schematic cross-sectional views illustrating structures and processes for forming an interconnect structure including a pre-formed hybrid bonding layer having a bonding surface, starting from the fabrication stage illustrated in FIG. 6. Meanwhile, FIGS. 16-20 present example processes of forming another embodiment of the support structure 227 shown in FIG. 7A above.

As with respect to FIG. 9, in FIG. 16 an extra interface layer 224 is deposited over the routing structure 220 including the conductive features 226 formed therein. The conductive features 226 can have a coarser pitch than the contact pads 214 of the hybrid bonding layer 215, e.g., serving as fan-out contact pads/terminals. As described with respect to FIG. 9 above, the separation (e.g., minimum pitch) between the adjacent contact pads 214 can be from 0.2 μm to 2 μm, from 0.5 μm to 5 μm or from 1 μm to 20 μm. The separation between the adjacent conductive features 226 can be equal to or greater than separation between the contact pads 214, for example, 2 to 10 times or 10 to 50 times greater than the separation between the contact pads 214. The minimum size (e.g., diameter or side width) of the contact pads 214 can be from 0.1 μm to 3 μm or from 1 μm to 10 μm, while the size of the conductive features 226 can be same or 2 to 10 times greater than the size of the contact pads 214. The cross-sectional areas of the contact pads 214 and/or the conductive feature 226 that is parallel to the upper surface 208 can take the same or different shapes (e.g., circular, square, hexagonal, etc.). The routing structure 220 may be expanded to include the interface layers 216, 224 below and above.

Referring to FIG. 17, a reconstituted layer 280 can be provided over the upper surface of the routing structure 220. The reconstituted layer 280 can comprise a substrate 281 (e.g., PCB, strip, panel, or an active or passive device, etc.) mounted (e.g., solder attached or adhesive attached) to the upper surface of the routing structure 220 of the interconnect structure 200 in FIG. 16. The reconstituted layer 280 is another example embodiment of the support structure 227 shown FIG. 7A above. The substrate 281 may comprise a device or a plurality of routing layers (e.g., metallization layers) therein, and comprises conductive features 286 (e.g., contact pads/terminals) disposed in an upper routing layer. The substrate 281 may be attached to the routing structure 220 via solder attachment, reconstitution, wafer level packaging (WLP) or ball grid array (BGA) packaging. For example, the conductive features 226 on the routing structure 220 may be attached to conductive features 284 disposed on the substrate 281 via solder bumps 282. In some embodiments, the space between the solder bumps 282 after the attachment process may be filled by an underfill layer 287, as shown in FIG. 17. Subsequently, a dielectric material 288 may be deposited to encapsulate the substrate 281 onto the routing structure 220 and to form the reconstituted layer 280, similar to the application of the dielectric material 270 to encapsulate the semiconductor devices 250, 260 onto the interconnect structure 200 shown in FIG. 13. In some embodiments, the substrate 281 (e.g., PCB) is attached (e.g., solder attached) to the interconnect structure 200 formed on the first temporary carrier 202 (e.g. carrier wafer or a panel) and encapsulated by a dielectric material to effectively form a reconstituted wafer or reconstituted panel 280 of the substrate 281 (e.g., reconstituted wafer or reconstituted panel of PCB). The routing layers in the interconnect structure 200 extend laterally beyond the edges of the substrate 281 or the routing/wiring on the PCB. The substrate 280 and the dielectric material 288 may provide sufficient mechanical support for subsequent fabrication processes. The conductive features 286 can be larger in size than the contact pads 214 of the hybrid bonding layer 215 and can be spaced by a courser pitch than the contact pads 214. As such, the conductive features 226 can connect to another device or substrate, e.g., by hybrid bonding or solder bonding. As with the descriptions for the conductive features 226 shown in FIG. 16, the conductive features 286 can have inter conductive feature separation equal to or greater than the separation of the contact pads 214 of the hybrid bonding layer 215, but possibly similar to the separation of the conductive features 226 of the routing structure 220. The size of the conductive features 286 can be the same as or at least 2 to 10 times greater than the size of the contact pads 214. The cross-sectional areas of the conductive feature 286 that is parallel to the upper surface 208 can take the same or different shapes (e.g., circular, square, hexagonal, etc.) with the contact pads 214 or the conductive features 226.

In FIG. 18, the carrier structure 201 including the first temporary carrier 202 is removed so that the hybrid bonding surface 230 is revealed. At this stage, the microelectronic structure becomes an interconnect structure 200A, comprising the interconnect structure 200 coupled with the substrate 280. In some embodiments, when warpage of the interconnect structure 200A is a concern and warpage balancing is desired, a second temporary carrier may be provided over the substrate 280 to further reinforce the microelectronic structure for subsequent fabrication. As described previously with respect to the interconnect structure 200, the hybrid bonding layer 215 having the bonding surface 230 is effectively transferred from the upper surface 208 of the carrier structure 201. Since the upper surface 208 of the carrier structure 201 is substantially flat, e.g., within 1 nm RMS surface roughness, the bonding surface 230 can also be substantially flat.

Forming a hybrid bonding layer on top of an organic substrate (e.g., PCB or panel, reconstituted wafer, etc.) is challenging via conventional sequential dielectric/metal layer deposition and polishing/CMP processes that are necessary for hybrid bonding due the large topographic variations of such substrates, such as PCB. Moreover, hybrid bonding is typically a fab process (e.g., process on a device fabrication line) that warrants stringent cleanliness requirements, while PCB manufacturing is typically performed on a packaging line with relatively lighter cleanliness requirements. Additionally, several materials in the conventional packaging line environment (e.g., encapsulation, molding compound, underfill, etc.) may not satisfy the cleanliness requirements of the significantly cleaner device fabrication lines due to contamination concerns. With the process flow described herein, the flat hybrid bonding layer 215 is formed on a cleaner fab line on top of carrier structure 201, transferring the routing structure 220 including the hybrid bonding layer 215 to the substrate 280 (e.g., PCB) can be performed on the less clean packaging line. Hence, the robust flat hybrid bonding layer can be formed on the organic substrate without contaminating the cleaner fabrication line with the unsuitable packaging materials.

After removing the carrier structure 201, the bonding surface 230 may go through preparation processes for hybrid bonding. In the illustrated embodiments, the preparation processes may not include CMP. In other embodiments, the preparation processes may include cleaning and CMP, e.g., a light CMP, to touch up the bonding surface, and plasma activation. The preparation processes for the bonding surface 230 may be substantially simpler than the preparation processes for conventionally formed semiconductor elements, because the bonding surface 230 is formed on and transferred from the substantially flat upper surface 208 of the carrier structure 201. As described above with respect to FIG. 11, the one or more contact pads 214 may be slightly dished if a CMP process is applied, or not dished if no CMP process is applied.

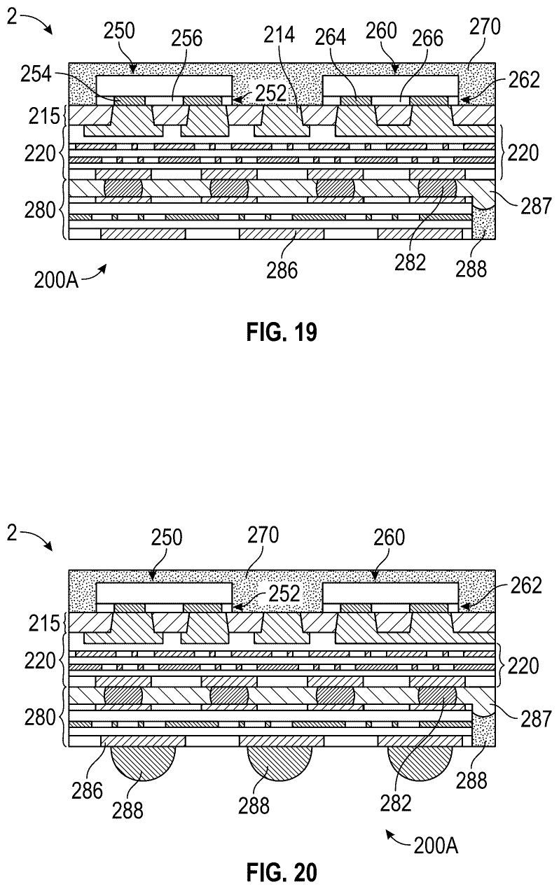

In FIG. 19, the interconnect structure 200A is flipped over to have the bonding surface 230 facing up. Subsequently, the interconnect structure 200A is directly bonded to at least one device, for example, two semiconductor devices 250, 260, as described above with respect to FIG. 12. As such a bonded structure 2 is formed comprising the interconnect structure 200A directly bonded with the semiconductor devices 250, 260. During the hybrid bonding process, the dielectric bonding layer 210 of the hybrid bonding layer 215 of the interconnect structure 200A is directly bonded to the dielectric material 256 of the hybrid bonding layer 252 of the semiconductor device 250 and to the dielectric material 266 of the hybrid bonding layer 262 of the semiconductor device 260 without an intervening adhesive. Likewise, the contact pads 214 of the hybrid bonding layer 215 are directly bonded to the conductive features 254 of the hybrid bonding layer 252 of the semiconductor device 250 and to the conductive features 264 of the hybrid bonding layer 262 of the semiconductor device 260 without an intervening adhesive. In some embodiments, another temporary carrier (e.g., silicon, glass, wafer/panel, dielectric layer, etc.) may be attached to the substrate or PCB side to minimize the warpage before bonding semiconductor devices 250, 260 to the hybrid bonding layer 215 on the opposite side. Each of the semiconductor devices 250, 260 can comprise the same or different devices, e.g., process die, memory die, or a stack of dies, as described above with respect to FIG. 12.

As shown in FIG. 20, solder bumps 288 are provided at the conductive features 286, so that the bonded structure 2 is prepared to be attached to another substrate, e.g., PCB. In other embodiments, the interface layer with contact features 286 can be prepared to hybrid bond to another element. In some embodiments, an encapsulant 270 or a dielectric material is deposited over the semiconductor devices 250, 260, embedding the semiconductor devices 250, 260 over the interconnect structure 200A, as shown in FIG. 20. In this way, the bonded structure 2 is further mechanically reinforced, as described with respect to FIG. 13 for bonded structure 1. The top surface of encapsulant 270 may be further polished or planarized.

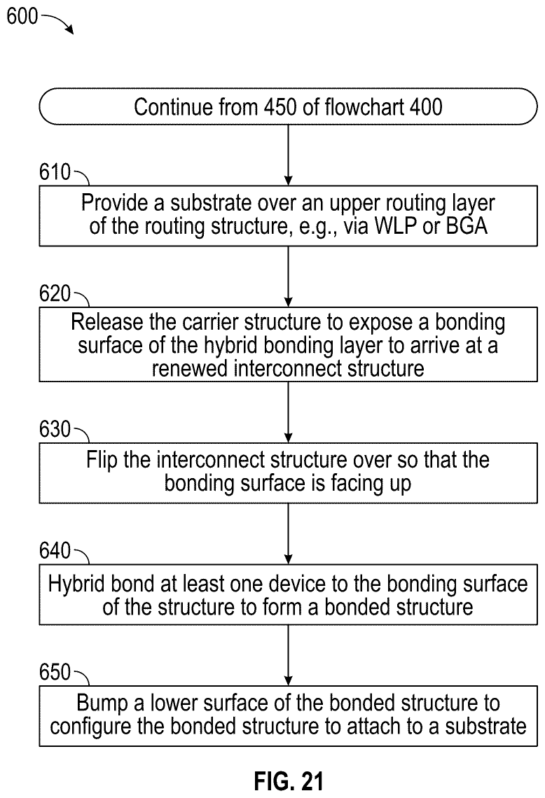

Referring to FIG. 21, a fabrication process flowchart 600 is illustrated to form the bonded structure 2 schematically shown in FIG. 20, starting from the assembly of the interconnect structure 200 coupled with the carrier structure 201 schematically shown in FIG. 6. According to flowchart 600, the process can be a continuation from the last stage of flowchart 400 shown in FIG. 8. At block 610, a substrate (e.g., PC board, PC strip, panel, etc.) is bonded to the interconnect structure, possibly via solder adhesion (e.g., BGA, reconstituted wafer, etc.). Attachment of substrate can further be re-enforcement by at least partially encapsulating the substrate. At block 620, the carrier structure including the first temporary carrier is removed to reveal a bonding surface of the hybrid bonding layer. The bonding surface may be prepared for hybrid bonding. At this stage the microelectronic structure becomes an interconnect structure including the attached or bonded substrate. At block 630, the strengthened interconnect structure is flipped over so that the bonding surface faces up. Subsequently at block 640, the interconnect structure is directly bonded to at least one semiconductor device to form a bonded structure. The dielectric material of the interconnect structure is directly bonded to a dielectric material of the semiconductor device without an intervening adhesive, and each contact pad of the interconnect structure is directly bonded to a conductive feature of the semiconductor device without an intervening adhesive. At block 650, a lower side of the interconnect structure is bumped, e.g., by solder balls, as such the bonded structure is configured to bond to another substrate, e.g., a PCB.

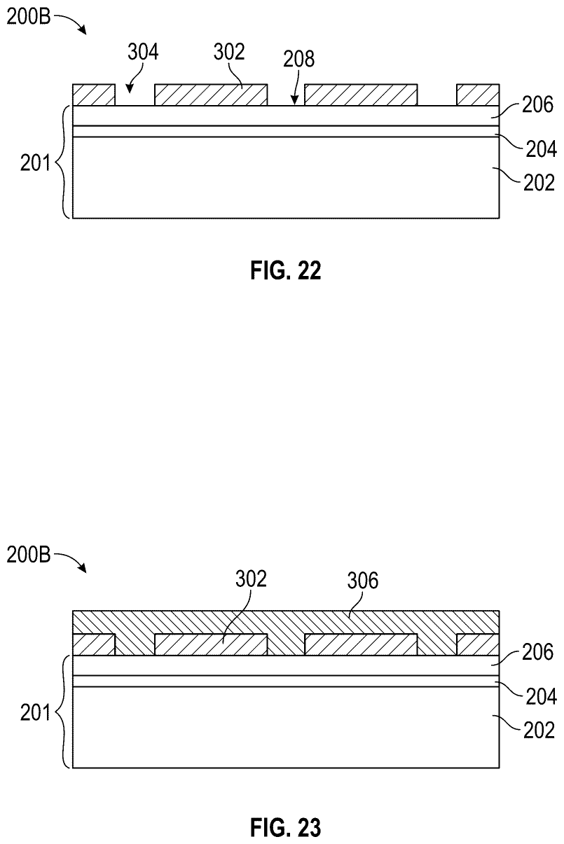

FIGS. 22-27 are schematic cross-sectional views illustrating processes for fabricating another interconnect structure embodiment and structures thereof. Certain fabrication processes and related structures have been described previously in details with respect to the interconnect structure 200 and the interconnect structure 200A. Thus, the descriptions to follow will be mostly directed to the processes and structures that are not covered above and specific to the embodiment of the interconnect structure to be discussed.

The embodiment shown in FIG. 22 starts from the structure shown in FIG. 3, where the carrier structure 201 is provided to include the first temporary carrier 202 for forming an interconnect structure thereon. Additionally, the carrier structure 201 can include the release layer 204 and the dielectric layer 206. As described with respect to FIG. 3, the release layer 204 may comprise a thermal release layer (e.g., which can be heated to release), an optical release layer (e.g., a UV or IR release layer in which case exposure to UV or IR light causes release), or a chemical release layer (e.g., exposure to a chemical species causes release). The upper surface 208 is formed to be substantially flat, e.g., within 1 nm RMS of surface roughness.

As shown in FIG. 22, a first dielectric layer 302 is provided over the upper surface 208 of the carrier structure 201, e.g., as a uniform dielectric layer, for fabrication of an interconnect structure 200B, such as a microelectronic structure, a microelectronic element, a semiconductor element or a semiconductor device. The first dielectric layer 302 may comprise a first dielectric material that is an inorganic dielectric material, e.g., silicon oxide, silicon nitride, silicon oxynitride, silicon carbide, silicon oxycarbonitride, silicon carbonitride, diamond-like carbon, low K dielectric material, and high K dielectric material. Subsequently, the first dielectric layer 302 is patterned and etched to form one or more vias, trenches or cavities 304 that penetrate through the first dielectric layer 302 and reaches the upper surface 208. The trenches 304 are connected to form a regular grid pattern, which will be further defined.

In FIG. 23, the cavities 304 are over filled with a second dielectric material so that the second dielectric material reaches and contacts the upper surface 208. The overfilling of the second dielectric material forms a second dielectric layer 306 over the first dielectric layer 302. The second dielectric material may comprise an organic dielectric material, e.g., polyimide (PI), polybenzoxazole (PBO), polymer, resin, epoxy, etc. As such the second dielectric layer 306 typically possesses more flexibility, e.g., bending flexibility, than the first dielectric layer 302 that comprises the inorganic dielectric material as described above for forming the first dielectric layer 302. The second dielectric may comprise compliant materials. For example, in some embodiments, Young's modulus of the second dielectric is less than 5 GPa, e.g., less than 3 GPa, or less than 1 GPa. In some embodiments, the second dielectric layer 306 comprises two or more dielectric layers of same or different organic dielectric materials. The first dielectric layer 302 and the second dielectric layer 306 can be considered as two sublayers of a combined dielectric layer for the interconnect structure 200B being built. The thickness of the second dielectric layer may range between 0.1 μm and 1 μm, or between 0.5 μm and 10 μm. In some embodiment, the second dielectric layer may be planarized before subsequent processes.

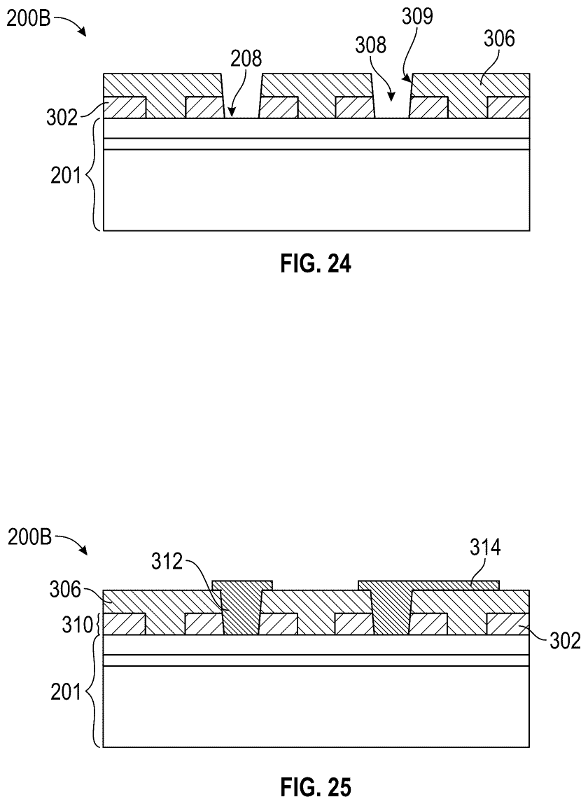

Referring to FIG. 24, the combined dielectric layer comprising the first dielectric layer 302 and the second dielectric layer 306 is patterned and etched to form one or more trenches or cavities 308 that penetrate through the second dielectric layer 306 and the first dielectric layer 302 and reach the upper surface 208 of the carrier structure 201. For example, in FIG. 24 two cavities 308 are shown. Similar to the sidewalls 213 described with respect to FIG. 4A, sidewalls 309 of the cavities 308 are typically sloped inwardly and downwardly, e.g., when the etching method is an isotropic etching process. For example, the wet etching method can comprise applying a potassium hydroxide (KOH) or tetramethylammonium hydroxide (TMAH) (or highly alkaline developer) solution for etching organic dielectric material (e.g., a photosensitive polymer), while wet etching can comprise buffered hydrofluoric acid (BFA), hydrofluoric acid, or hexafluoroethane (C₂F₆) plasma etching) solution(s) for etching inorganic dielectric material. For each cavity 308, such sloped sidewalls 309 typically result in a smaller cross-sectional area of the cavity that is parallel to the upper surface 208 at a location close to the upper surface 208 than a cross-sectional area away from the upper surface 208 and close to an upper surface of the second dielectric layer 306. In some embodiments, the sidewalls 309 can be formed substantially vertical, e.g., when the etching method is an anisotropic etching process (e.g., drying etching, DRIE). In some embodiments, the second dielectric layer 306 may comprise a high temperature photo sensitive polymer having a coefficient of thermal expansion (CTE) less than 30 ppm/° C., desirably less than 15 ppm/° C. In this way, the cavities 308 may be formed by lithographic methods.

In FIG. 25, the cavities 308 are over filled with a conductive material to form one or more conductive contact pads (e.g., contact features) 312 and an interface layer 314 over the second dielectric layer 306. In some embodiments, the conductive contact pads 312 and an interface layer 314 are simultaneous formed in a dual damascene process (e.g., copper dual damascene process). The conductive material can comprise a metal, such as copper, nickel, chromium, gold, indium, tin, platinum, silver, ruthenium, molybdenum, palladium, cobalt, zinc, tungsten, tantalum, titanium, aluminum, a metal silicide, and alloys thereof, or a non-metal conductive material, e.g., doped silicon. As shown in FIG. 25, the contact pads 312 are disposed penetrating the first dielectric layer 302 and the second dielectric layer 306. The contact pads 312 and the first dielectric layer 302 together form a hybrid bonding layer (e.g., part of an interconnect structure) 310, with portions of the second dielectric layer 306 interspersed therethrough. Thus, a lower surface of the hybrid bonding layer 310, comprising the first dielectric material 302, and the contact pads 312, are exposed at the upper surface 208. FIG. 25 further shows that the interface layer 314 may be patterned and etched to form gaps between adjacent traces.

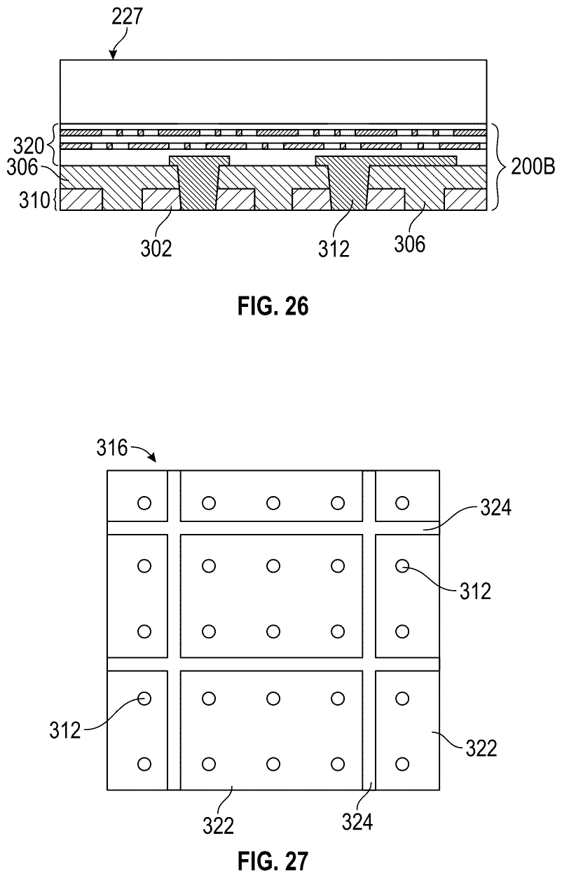

In FIG. 26, a routing structure 320 comprising one or more redistribution layers is provided over the interface layer 314. In some embodiments, the routing structure 320 may comprise one or more dielectrics with embedded conductive vias and traces, device layers, or metallization layers, formed over the interface layer 314. In some embodiments, the routing structure 320 may comprise semiconductor, inorganic, or organic materials. In some embodiments, one or more dielectric layers of routing structure 320 can comprise organic materials (e.g., polyimide, PBO, polymer, epoxy, resin, etc.) and/or inorganic materials (silicon oxide, silicon nitride, etc.). A support structure 227 is provided over (e.g., directly bonded to or solder attached to) the routing structure 320 of the interconnect structure 200B, forming a microelectronic assembly comprising the interconnect structure 200B coupled with the carrier structure 201 at the underside and the support structure 227 at upper side. The support structure 227 can structurally reinforce the interconnect structure 200B, and can take different forms or embodiments. The support structure 227 can serve as a handle (e.g., handle wafer) to support the released interconnect structure 200B as the interconnect structure 200B is directly bonded to another surface or structure. Subsequently, the carrier structure 201 including the first temporary carrier 202 is removed so that a bonding surface 316, which is the lower surface of the hybrid bonding layer 310, is released and exposed. The removing processes was described previously in details with respect to FIG. 10.

The microelectronic assembly as shown in FIG. 26 resembles a stage of the assembly shown in FIG. 7A or 7B. Hereafter, the microelectronic structure can be further processed to form a bonded structure, for example, following the processes of flowchart 500 to form a bonded structure similar to the bonded structure 1 (e.g., with semiconductor dies), or following the processes of flowchart 600 to form a bonded structure similar to the bonded structure 2 (e.g., with organic substrates like PCBs).

FIG. 27 is a schematic plan view of the interconnect structure 200B showing the bonding surface 316 after the carrier structure 201 is removed. As described above with respect to FIGS. 10-11, since the bonding surface 316 is transferred from a substantially flat upper surface 208, it is substantially flat. As can be seen in FIG. 27, the bonding surface 316 comprises dielectric material regions 322 comprising the inorganic dielectric material that forms the first dielectric layer 302, the contact pads 312 embedded in the dielectric material regions 322, and grid lines 324 comprising the organic dielectric material that forms the second dielectric layer 306, as described with respect to FIGS. 22-25.

In FIG. 27, the dielectric material regions 322 are the exposed surfaces of the first dielectric layer 302 and the grid lines 324 are the exposed surfaces of the second dielectric layer 306. As shown in FIG. 27, the grid lines 324 are connected forming a rectangular grid pattern that is spread to cover the entire bonding surface 316. In other embodiments, the grid lines 324 can be connected to form patterns that take other shapes, e.g., triangular, hexagonal, quadrilateral, polygonal, circular, curved, irregular, or combination thereof. Since the organic dielectric material forming the grid lines 324 (e.g., second dielectric layer materials) is compliant or more flexible than the inorganic dielectric material forming the dielectric material regions 322 (e.g., first dielectric layer materials), when the routing structure 320 comprises organic material(s), the interconnect structure 200B may be able to bend at the grid lines 324 that covers the bonding surface 310. Although the hybrid bonding layer 310 comprises hard (or stiff) inorganic material (e.g., silicon oxide, silicon oxynitride, silicon carbonitride, etc.), the intermittent grid lines 324 formed of compliant materials effectively form smaller disconnected islands of such hard (or stiff) inorganic dielectric material regions 322 which effectively makes the hybrid bonding layer 310 more flexible or compliant to warping. Thus, the interconnect structure 200B can be flexible and can be made to fit to different surface topologies, thermal/mechanical stresses and package warpages. The level of flexibility of the interconnect structure 200B may depend on the flexibility of the organic dielectric materials used, the density of the grid lines 324 disposed on the bonding surface 316, the width of each of the grid lines 324 or the trenches 304 for forming the grid lines 324, among other factors.

In the illustrated embodiment, the interconnect structure 200B is hybrid bonded to another element, such that the inorganic dielectric material regions 322 are directly bonded to an opposing dielectric material of the element, and the contact pads are directly bonded to opposing conductive features of the element. The grid lines 324 may be at least partially embedded the hybrid bonding layer. The grid lines may not form a bond with an opposing material, or may form an adhesive bond with an opposing material.

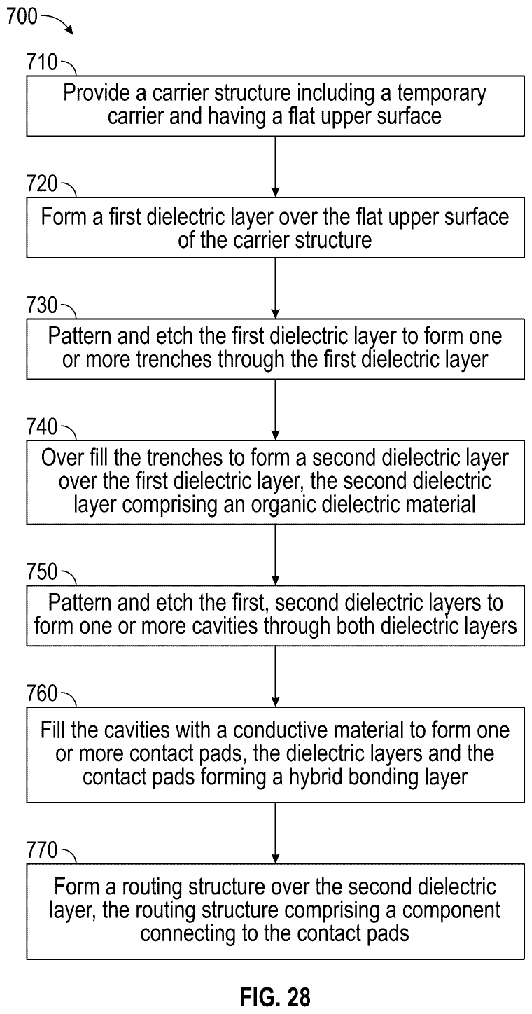

Referring to FIG. 28, the fabrication method to fabricate the interconnect structure 200B described above with respect to FIGS. 22-27 are further illustrated as a process flowchart 700. According to flowchart 700, at block 710 a carrier structure is provided to have a substantially flat upper surface. The carrier structure comprises a temporary carrier, and may further comprise a release layer and a dielectric layer. At block 720, a first dielectric layer is provided over the upper surface of the carrier structure. the first dielectric layer comprises an inorganic dielectric material. At block 730, the first dielectric layer is patterned and etched to form one or more trenches that go through the first dielectric layer and reach the upper surface. The trenches are connected forming a grid pattern. At block 740, the one and more trenches are over filled with a second dielectric material. The second dielectric material comprises an organic dielectric material and forms a second dielectric layer over the first dielectric layer. The trenches filled with the organic dielectric material may form grid line pattern to give structural flexibility to the interconnect structure being formed. At block 750, the first and second dielectric layers are patterned and etched to form one or more vias, cavities or trenches that go through the first and second dielectric layers and reach the upper surface. Sidewalls of the cavities may be sloped inwardly so that a cross-sectional area of each cavity that is parallel to the upper surface of the carrier structure and located close to the upper surface of the carrier structure is smaller than a cross-sectional area of the cavity away from the upper surface of the carrier structure and close to an upper surface of the second dielectric layer. In some embodiments, the sidewalls can be formed vertically depending on the etching method used. At block 760, the cavities are filled with a conductive material to form one or more contact pads. The first dielectric layer and the contact pads together form a hybrid bonding layer. The second dielectric layer may not perform bonding action when the interconnect structure is hybrid bonded to another element. At block 770, a routing structure is provided over the hybrid bonding layer and the second dielectric layer. The routing structure may comprise a device or component that is connected to the contact pads of the hybrid bonding layer. Subsequently, the carrier structure may be removed, e.g., through one or more of etching, polishing/grinding and thermal/light/chemical releasing processes depending on the construction of the carrier structure, to expose a bonding surface of the hybrid bonding layer. The bonding surface may be prepared and hybrid bonded to another element, In one aspect of the present invention, a method for forming a bonded structure comprises providing a first carrier having an upper surface, providing a bonding structure over the upper surface of the first carrier, where the bonding structure comprises a contact pad at least partially embedded in a first dielectric material, and a first surface of the bonding structure comprising the first dielectric material and the contact pad is adjacent the upper surface of the first carrier, providing a routing structure over a second surface of the bonding structure, removing the first carrier to expose the first surface, and hybrid bonding the first surface of the bonding structure to another element. In some embodiments, a dishing of the contact pad at the first surface is less than 1 nm. In some embodiments, the upper surface is substantially flat; the first surface is substantially flat. In some embodiments, the method further comprises providing a dielectric layer between the first carrier and the bonding structure.

In some embodiments, the method further comprises providing a release layer between the first carrier and the bonding structure. In some embodiments, the release layer comprises a thermal release layer, where the release layer comprises an optical release layer or a chemical release layer. In some embodiments, the routing structure comprises an electrical device.

In some embodiments, the method further comprises providing a second carrier over the routing structure, directly bonding the first surface of the bonding structure to a semiconductor device, where the first dielectric material is directly bonded to a dielectric material disposed in a bonding layer of the semiconductor device and the contact pad is directly bonded to a conductive feature embedded in the dielectric material of the bonding layer of the semiconductor device, removing the second carrier, and configuring the routing structure for bonding to a substrate. In some embodiments, providing a second carrier over the routing structure is before removing the first carrier.

In some embodiments, the method further comprises depositing an encapsulant material embedding the semiconductor device, where depositing the encapsulant material is before removing the second carrier.

In some embodiments, the method further comprises providing a support structure over the routing structure, and directly bonding the first surface of the bonding structure to a semiconductor device, where the first dielectric material is directly bonded to a dielectric material disposed in a bonding layer of the semiconductor device and the contact pad is directly bonded to a conductive feature embedded in the dielectric material of the bonding layer of the semiconductor device. In some embodiments, the method further comprises configuring the support structure for bonding to a substrate. In some embodiments, providing the support structure is before removing the first carrier. In some embodiments, the support structure comprises an organic substrate, an organic strip, or an organic flat panel. In some embodiments, providing the support structure is via wafer level processing (WLP); providing the support structure is via ball grid array (BGA) processing.

In some embodiments, the method further comprises depositing an encapsulant material embedding the support structure where depositing the encapsulant material is before removing the first carrier. In some embodiments, the method further comprises providing a second carrier over the support structure.

In some embodiments, the bonding structure further comprises an organic dielectric material, where the organic dielectric material is disposed forming a second dielectric layer over the first dielectric material and through discrete trenches formed in the first dielectric material to reach and be exposed at the upper surface. In some embodiments, the organic dielectric material exposed at the upper surface forms a gridline pattern.

In another aspect of the present invention, a method for forming an interconnect structure comprises depositing a first dielectric layer over a first carrier, the first carrier having an upper surface, patterning the first dielectric layer to form at least one cavity through the first dielectric layer, filling the at least one cavity with a conductive material to form a contact pad, providing a routing structure over the first dielectric layer and the conductive material, and removing the first carrier to expose a hybrid bonding surface comprising the first dielectric layer and the contact pad.

In some embodiments, the upper surface is substantially flat. In some embodiments, the routing structure comprises metallization layers.

In some embodiments, the method further comprises providing a second carrier over the routing structure, directly bonding the hybrid bonding surface to a semiconductor device, where the first dielectric layer is directly bonded to a dielectric material disposed in a bonding layer of the semiconductor device without an intervening adhesive and the contact pad is directly bonded to a conductive feature embedded in the dielectric material of the bonding layer of the semiconductor device without an intervening adhesive, removing the second carrier, and configuring the routing structure for bonding to a substrate. In some embodiments, providing a second carrier over the routing structure is before removing the first carrier. In some embodiments, the method further comprises depositing a dielectric material encapsulating the semiconductor device.

In some embodiments, the method further comprises providing a support structure over the routing structure, and directly bonding the hybrid bonding surface to a semiconductor device, wherein the first dielectric layer is directly bonded to a dielectric material disposed in a bonding layer of the semiconductor device without an intervening adhesive and the contact pad is directly bonded to a conductive feature embedded in the dielectric material of the bonding layer of the semiconductor device without an intervening adhesive. In some embodiments, the method further comprises configuring the support structure for bonding to a substrate. In some embodiments, providing the support structure is before removing the first carrier. In some embodiments, the method further comprises depositing a dielectric material encapsulating the support structure.

In some embodiments, the method further comprises patterning the first dielectric layer to form trenches having a gridline pattern, the trenches reaching the upper surface, providing an organic dielectric material over the first dielectric layer forming a second dielectric layer and filling the trenches, and wherein the at least one cavity is formed through the first dielectric layer and the second dielectric layer to receive the conductive material to form the contact pad.

In another aspect of the present invention, an interconnect structure comprises a routing structure, a bonding layer coupled with the routing structure and having a hybrid bonding surface, the bonding layer comprising a dielectric layer and a conductive contact feature at least partially embedded in the dielectric layer, wherein a cross-sectional area of the conductive contact feature increases with a distance from the hybrid bonding surface, wherein the cross-sectional area is parallel with the hybrid bonding surface.

In some embodiments, the hybrid bonding surface is substantially flat; a maximum surface roughness of a dielectric portion of the hybrid bonding surface is less than 1 nm RMS; the routing structure comprises a microelectronic device; the routing structure comprises a back end of line (BEOL) structure; the routing structure is configured to solder-attach to a substrate.

In some embodiments, the interconnect structure further comprises a substrate solder-attached to the routing structure, wherein the substrate is a silicon substrate, glass substrate or PCB.

In some embodiments, the dielectric layer comprises a first dielectric sublayer and a second dielectric sublayer, where the second dielectric sublayer is disposed between the first dielectric sublayer and the routing structure, and the second dielectric sublayer penetrates through the first dielectric sublayer at discrete locations forming a gridline pattern exposing at the hybrid bonding surface. In some embodiments, the first dielectric sublayer comprises an inorganic dielectric material and the second dielectric sublayer comprises an organic dielectric material.

In another aspect of the present invention, a bonded structure comprises an interconnect structure and a semiconductor element directly bonded to the bonding surface of the interconnect structure. The interconnect structure comprises a routing structure, a hybrid bonding layer coupled with the routing structure and having a bonding surface, the hybrid bonding layer comprising a dielectric material and a conductive contact feature at least partially embedded in the dielectric material where the conductive contact feature has a first width at the bonding surface and a second width away from the bonding surface, the second width larger than the first width. In some embodiments, a maximum surface roughness of the bonding surface is less than 1 nm RMS. In some embodiments, the semiconductor element is encapsulated in a dielectric material. In some embodiments, the interconnect structure further comprises a substrate solder-attached to the routing structure. In some embodiments, the dielectric layer of the interconnect structure comprises a first dielectric sublayer and a second dielectric sublayer, where the second dielectric sublayer is disposed between the first dielectric sublayer and the routing structure, and the second dielectric sublayer penetrates through the first dielectric sublayer at discrete locations forming a gridline pattern exposing at the bonding surface.

In another aspect of the present invention, an interconnect structure comprises a routing structure, a bonding structure coupled with the routing structure having a hybrid bonding surface, where the bonding structure comprises a dielectric layer, a contact pad forming part of the bonding structure, where the contact pad is at least partially embedded in the dielectric layer and is disposed adjacent a sidewall of a cavity formed in the dielectric layer, and the contact pad is exposed at the hybrid bonding surface, and the sidewall of the cavity is sloped outwardly away from the hybrid bonding surface.

In some embodiments, the routing structure comprises a device. In some embodiments, the interconnect structure further comprises a substrate solder-attached to the routing structure, where the substrate is a silicon substrate, glass substrate, or PCB. In some embodiments, the dielectric layer comprises a first dielectric sublayer and a second dielectric sublayer, where the second dielectric sublayer is disposed between the first dielectric sublayer and the routing structure, and the second dielectric sublayer penetrates through the first dielectric sublayer at discrete locations forming a gridline pattern exposing at the hybrid bonding surface. the first dielectric sublayer comprises an inorganic dielectric material and the second dielectric sublayer comprises an organic dielectric material.

In another aspect of the present invention, a bonding method comprises hybrid bonding a hybrid bonding surface of a first element to a second element without performing a chemical mechanical polishing (CMP) process on the hybrid bonding surface. In some embodiments, the method further comprises depositing a first dielectric layer over a first carrier and at least partially embedding a plurality of contact pads in the first dielectric layer, where the first dielectric layer and the plurality of contact pads form a bonding layer having the hybrid bonding surface. In some embodiments, the method further comprises providing a routing structure over the bonding layer. In some embodiments, the method further comprises removing the first carrier to expose the hybrid bonding surface before the hybrid bonding.

In another aspect of the present invention, a bonded structure comprises an interconnect structure having a first side including a hybrid bonding surface and a second side opposite the first side, an element hybrid bonded to the hybrid bonding surface of the interconnect structure, a substrate attached to the second side of the interconnect structure by way of solder balls, and an encapsulant in which the substrate is at least partially embedded. In some embodiments, the bonded structure further comprises a second encapsulant in which the element is at least partially embedded.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method for forming a bonded structure; comprising:
providing a first carrier having an upper surface;
providing a bonding structure over the upper surface of the first carrier, wherein the bonding structure comprises a contact pad at least partially embedded in a first dielectric material, and wherein a first surface of the bonding structure comprising the first dielectric material and the contact pad is adjacent the upper surface of the first carrier;
providing a routing structure over a second surface of the bonding structure;
removing the first carrier to expose the first surface; and
hybrid bonding the first surface of the bonding structure to another element.

2. The method of claim 1, wherein a dishing of the contact pad at the first surface is less than 1 nm.

3. (canceled)

4. The method of claim 1, wherein the first surface is substantially flat.

5. (canceled)

6. The method of claim 1, further comprising providing a release layer between the first carrier and the bonding structure.

7. The method of claim 6, wherein the release layer comprises a thermal release layer.

8. The method of claim 6, wherein the release layer comprises an optical release layer.

9. The method of claim 6, wherein the release layer comprises a chemical release layer.

10. The method of claim 1, wherein the routing structure comprises an electrical device.

11. The method of claim 1, further comprising:
providing a second carrier over the routing structure;
directly bonding the first surface of the bonding structure to a semiconductor device, wherein the first dielectric material is directly bonded to a dielectric material disposed in a bonding layer of the semiconductor device and the contact pad is directly bonded to a conductive feature embedded in the dielectric material of the bonding layer of the semiconductor device;
removing the second carrier; and
configuring the routing structure for bonding to a substrate.

12. The method of claim 11, wherein providing a second carrier over the routing structure is before removing the first carrier.

13. The method of claim 11, further comprising depositing an encapsulant material embedding the semiconductor device.

14. The method of claim 13, wherein depositing the encapsulant material is before removing the second carrier.

15. The method of claim 11, further comprising:
providing a support structure over the routing structure; and
directly bonding the first surface of the bonding structure to a semiconductor device, wherein the first dielectric material is directly bonded to a dielectric material disposed in a bonding layer of the semiconductor device and the contact pad is directly bonded to a conductive feature embedded in the dielectric material of the bonding layer of the semiconductor device.

16.-25. (canceled)

26. A method for forming an interconnect structure; comprising:
depositing a first dielectric layer over a first carrier, the first carrier having an upper surface;
patterning the first dielectric layer to form at least one cavity through the first dielectric layer;
filling the at least one cavity with a conductive material to form a contact pad;
providing a routing structure over the first dielectric layer and the conductive material; and
removing the first carrier to expose a hybrid bonding surface comprising the first dielectric layer and the contact pad.

27. The method of claim 26, wherein the upper surface is substantially flat.

28.-31. (canceled)

32. The method of claim 26, further comprising:
providing a support structure over the routing structure; and
directly bonding the hybrid bonding surface to a semiconductor device, wherein the first dielectric layer is directly bonded to a dielectric material disposed in a bonding layer of the semiconductor device without an intervening adhesive and the contact pad is directly bonded to a conductive feature embedded in the dielectric material of the bonding layer of the semiconductor device without an intervening adhesive.

33. The method of claim 32, further comprising configuring the support structure for bonding to a substrate.

34.-35. (canceled)

36. The method of claim 26, further comprising:
patterning the first dielectric layer to form trenches having a gridline pattern, the trenches reaching the upper surface;
providing an organic dielectric material over the first dielectric layer forming a second dielectric layer and filling the trenches; and
wherein the at least one cavity is formed through the first dielectric layer and the second dielectric layer to receive the conductive material to form the contact pad.

37. An interconnect structure comprising:
a routing structure;
a bonding layer coupled with the routing structure and having a hybrid bonding surface, the bonding layer comprising:
a dielectric layer and a conductive contact feature at least partially embedded in the dielectric layer, wherein a cross-sectional area of the conductive contact feature increases with a distance from the hybrid bonding surface, wherein the cross-sectional area is parallel with the hybrid bonding surface.

38.-41. (canceled)

42. The interconnect structure of claim 37, wherein the routing structure is configured to solder attach to a substrate.

43.-63. (canceled)
